(19) United States
(12) Patent Application Publication
(10) Pub. No.: US 2025/0348214 A1
(43) Pub. Date: Nov. 13, 2025

(54) ACCESS TIME CALCULATOR CIRCUIT, CORRESPONDING MEMORY DEVICE AND METHOD

(71) Applicant: STMicroelectronics International N.V., Geneva (CH)

(72) Inventors: Diego DE COSTANTINI, Augusta (SR) (IT); Marco Eugenio GIBILARO, Aci Castello (CT) (IT); Francesco TOMAIUOLO, Acireale (CT) (IT)

(73) Assignee: STMicroelectronics International N.V., Geneva (CH)

(21) Appl. No.: 19/199,529

(22) Filed: May 6, 2025

(30) Foreign Application Priority Data
May 7, 2024 (IT) 102024000010195

(51) Int. Cl. G06F 3/06

(52) U.S. Cl. CPC G06F 3/0604; G06F 3/0659; G06F 3/0673

(57) ABSTRACT

Memory access time is determined via an access time calculator including a read data port coupled to a memory storing alternate runs of data at different memory addresses. The read data port receives data read from the memory with a memory access time in a sequence of read events from different memory addresses. The data read in subsequent read events in the sequence exhibits toggling in response to the alternate runs of data. An edge detector detects toggling of data read from the memory which indicates the end of a previous read event in the sequence of read events. Triggering circuitry coupled to the edge detector produces a trigger signal to start a new read event in the sequence of read events in response to detected toggling. A duration of the alternate runs of data in the sequence of read events is indicative of the access time to the memory.

### PRIORITY CLAIM

This application claims the priority benefit of Italian Application for Patent No. 102024000010195 filed on May 7, 2024, the content of which is hereby incorporated by reference in its entirety to the maximum extent allowable by law.

### TECHNICAL FIELD

The description relates to electronic memories.

Aspects of the present description can be used in non-volatile memories (NVMs) whenever an accurate measurement of access time is desired at NVM level.

### BACKGROUND

Flash technology and floating gate transistor technology currently represent the dominant technologies for electronic non-volatile memory (NVM) storage that can be electrically erased and reprogrammed.

This scenario is subject to change (for scaling and cost reasons, for instance) and is moving towards other solutions such as solutions based on magneto-resistive random-access memory (MRAM) technology and phase change memory (PCM) technology.

Read access time is becoming faster (that is, shorter) and the ability of measuring read access time in an automatic and accurate way is a desirable feature. Access time may, in fact, represent an indicator of the quality of a memory.

Access time can be measured by comparing the associated timing against the period of a reference clock. An accurate measurement may, however, involve a (very) high frequency of the external clock.

Read access time can be measured by launching a read instruction using external machines during electrical wafer sorting (EWS), where EWS refers to the operation of electrically testing dice on a silicon wafer. This approach is time consuming, and input and output delays in an external data path may result in the measured access time being different from the time experienced by the memory, with measurement errors proportional to the variations the EWS machine can apply to the clock period.

There is a need in the art to contribute in addressing the issues discussed in the foregoing.

### SUMMARY

One or more embodiments relate to a circuit.

One or more embodiments relate to a corresponding device. A non-volatile memory (NVM) embedded in a system-on-chip (SOC) and using a circuit as described herein may be exemplary such a device.

It is otherwise noted that possible applications of solutions as described herein are not limited to NVM memories embedded in a SOC. Solutions as described herein can be used whenever an accurate measurement of access time (not affected by external paths) is desired at NVM level.

One or more embodiments relate to a corresponding method.

Solutions as described herein are essentially independent from the memory technology involved and can be notionally applied to any type of memory.

Solutions as described herein facilitate an accurate measurement of read access time using a “slow” clock as a reference.

A basic idea underlying the solutions as described herein is to use toggling of data read from the memory to generate a new clock and to use this new clock to launch a new reading.

The readings are counted up to a predefined number and the entire duration is measured using a (low frequency) external clock.

Solutions as described herein can use a finite state machine (FSM) to launch a sequence of N reads at different addresses with alternate data with each toggle of the data triggering the start of a next read.

Each read will then start independently of the external clock in so far as it is driven (only) by the end of previous read.

Commutation (switching) of data can be then be used to create a new clock with a period equal to twice the access time.

In solutions as described herein, an external clock is used only to measure the entire length of the full run, and errors in the average measure will be plus or minus one full clock cycle (FCLK) over the entire run.

Solutions as described herein facilitate achieving improved accuracy in measuring the access time of a non-volatile memory (NVM), in so far as measurement is not affected by the external data path, with automatic access time calculation for the entire array, with a marked reduction of testing time.

Solutions as described herein offer one or more of the following advantages: improved accuracy in measuring access time to a non-volatile memory (NVM), with results not affected by an external data path; automatic access time calculation in an entire memory array, with an ensuing reduction of testing time; access time calculator embedded in the NVM; and reading started automatically in response to commutation (switching) of the previous one, without being delayed by the external clock.

### BRIEF DESCRIPTION OF THE DRAWINGS

One or more embodiments will now be described, by way of example only, with reference to the annexed figures, wherein:

FIG. 1 is a block diagram exemplary of circuit architecture as described herein;

FIG. 2 is a circuit diagram of possible implementation details of circuit architecture as described herein;

FIG. 3 is a diagram showing possible time behaviors of signals that may occur in circuit architecture as described herein; and

FIG. 4 is exemplary of possible application of circuit architecture as described herein in a system on chip (SOC).

### DETAILED DESCRIPTION

The figures are drawn to clearly illustrate the relevant aspects of the embodiments and are not necessarily drawn to scale.

The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Once more, for the sake of simplicity and ease of explanation, a same designation may be applied throughout this description to designate: a certain node or line as well as a signal occurring at that node or line, and/or a certain component (such as a capacitor, resistor or inductor of coil) as well as electrical parameters thereof.

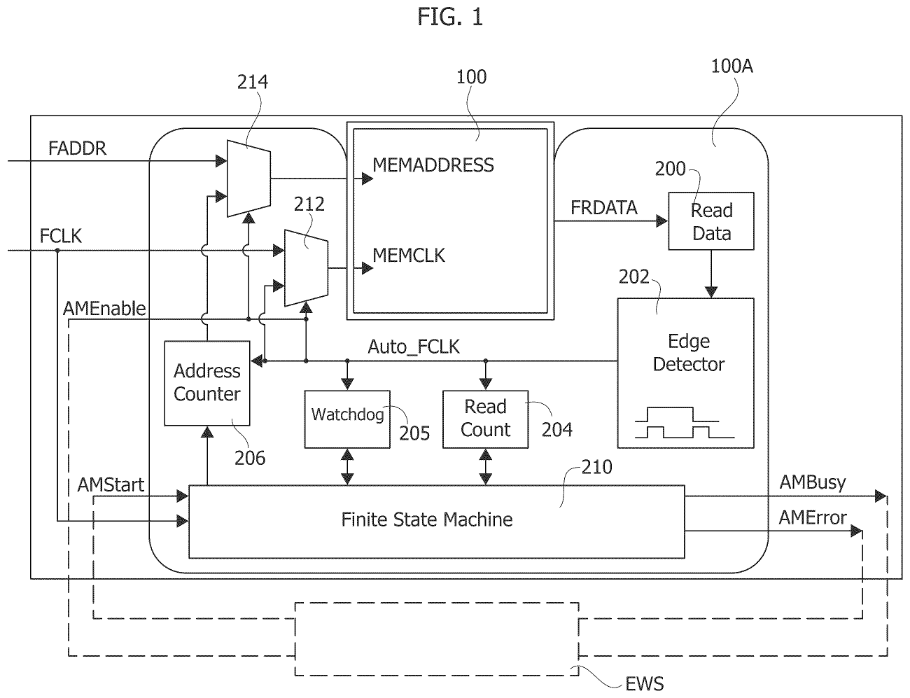

FIG. 1 is a block diagram that schematically represents circuit architecture built around a memory array 100 such as a non-volatile memory (NVM) array.

Memory circuitry based on flash technology, floating gate transistor technology, magneto-resistive random-access memory (MRAM) technology and phase change memory (PCM) technology may be exemplary of such a memory array 100.

It is otherwise noted that solutions as described herein are essentially independent from the memory technology involved. These solutions can be notionally applied to any type of memory where an accurate measurement of access time (not affected by external paths) is desired at memory level.

As exemplified herein, access to the memory array represented by reference 100 takes place at addresses selected on the basis of an input signal MEMADDRESS.

Access to the memory array 100 is synchronized with a clock signal, so that reading will start at the rising edge of the MEMCLK.

The outcome of access to the array 100 (data read therefrom, in the case primarily considered here) is provided as an output signal FRDATA and is assumed to take place after a delay versus the start of the reading. This delay is commonly called Access Time and is a parameter of the memory which indicates the time needed for each reading in array.

The element 100 discussed so far can be regarded as a conventional “old logic” circuitry; structure and operation of such circuitry are not described in further detail here for brevity in so far as these are known to those of skill in the art.

As discussed, read access time is becoming faster and the ability of measuring that time in an automatic and accurate way is a desirable feature.

Access time can be measured by comparing the associated timing against the period of a reference clock.

For instance, read access time can be measured launching a read instruction and checking if the data is correct. This can be done using external machines during electrical wafer sorting (EWS), referring to the operation of electrically testing dice on a silicon wafer. The EWS test machines used for that purpose must be able then to launch a reading, check the result, and—if the data is correct—try to sample the data at higher frequency, or—if the data is not correct—try to slow down the frequency. On order to obtain an access time for the fastest and slowest word in the memory this is done for all the words in the array. The related error on the measurement is proportional to the variation the EWS machine is able to apply to the period of the clock.

Also: access time measured via word-by-word reading using external test machines and varying the clock period requires a non-negligible amount of time especially for large memory cuts, and measurement is affected by input and output delay of the external data-path, so the measured access time is not exactly the one coming from the memory.

Solutions as exemplified herein facilitate an accurate measurement of read access time using a “slow” clock FCLK as a reference.

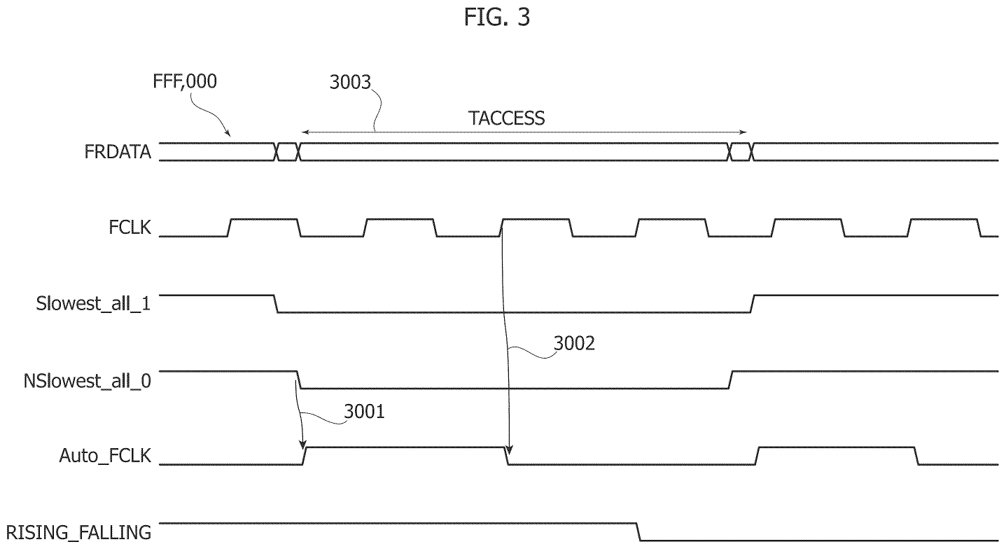

For instance, assuming access time to the memory 100 has an associated timing of 30 ns (this of course is a merely exemplary, non-limiting value), solutions as described herein facilitate calculating access time (TACCESS in FIG. 3, discussed later) by comparing the associated timing against the period of a reference clock FCLK generated—in a manner known to those of skill in the art—with a (relatively low) frequency corresponding to a period of 10 ns (again, this is a merely exemplary, non-limiting value).

A basic idea underlying the solutions as exemplified herein is to use toggling of data FRDATA read from the memory 100 to generate a new clock (Auto_FCLK) and to use this new clock to launch a new reading. The readings are counted up to a predefined number and the entire duration is be measured using a (low frequency) external clock such as FCLK.

To that effect, the data FRDATA read from the memory 100 are sent to a read data port 200 and then on to an edge detector 202 to produce the “automatic” clock signal Auto FCLK.

Reference 204 indicates a block used to count the number of readings performed. Read count is increased at each rising edge of the signal Auto_FCLK input to the block 204. Reference 205 indicates a watchdog circuit, used to detect a possible excessive duration of any reading.

Reference 206 indicates an address calculator circuit, that generates an increased address value at each rising edge of the signal Auto_FCLK, so that a sequence of read events takes place at different addresses.

Reference 212 denotes a first multiplexer that causes the input MEMCLK of the memory array 100 to have applied thereto: the “external” clock signal FCLK, or the “automatic” clock signal Auto_FCLK from the edge detector 202.

In that way the toggling of data FRDATA read from the memory 100 can be used to launch a new reading in response to the signal Auto_FCLK.

Reference 214 denotes a second multiplexer that causes the input MEMADDRESS of the memory array 100 to have applied thereto: an “external” address signal FADDR, or an “internal” address calculated in the address calculator 206.

Operation (switching) of the multiplexers 212 and 214 is under the control of a memory access enable signal AMEnable generated in manner known per se to those of skill in the art.

Reference 210 denotes a Finite State Machine (FSM) that cooperates with the read counter 204, the watchdog circuit 205 and the address calculator 206 in order to control the flow of the read events from the memory array 100, with the capability of stopping (access time) measurement in response to either a last read event having occurred or a watchdog error being detected.

The FSM 210 is configured to be coupled to a test machine to be driven thereby.

Advantageously, such a test machine can be implemented based on conventional test equipment configured to perform the operation of electrically testing dice on a silicon wafer currently referred to as electrical wafer sorting (EWS). For that reason, the test machine illustrated in FIG. 1 is labeled EWS.

It will be appreciated that the test machine EWS is, per se, a distinct element from the access time calculator circuit indicated by the reference 100A in FIG. 1.

Solutions as described herein are in fact primarily concerned with the structure and operation of the circuit 100A as a separate entity, intended to be associated with a memory array 100 and to cooperate with a test machine during EWS testing in calculating the access time of the memory array 100.

To that effect, an exemplary circuit 100A as described herein comprises the read data port 200 configured to be coupled to a memory array 100 having stored therein alternate runs of data (FFF, 000, for instance, where a “run” of data is understood to mean consecutive occurrences of a same data bit value, such as all logic “1” bits for the data (in the hexadecimal FFF example) or all logic “0” bits for the data (in the hexadecimal 000 example), and “alternate” is understood to mean alternating logically opposite bit state), in a sequence of bits stored at different memory addresses. The read data port is configured to receive data such as FRDATA read (with a memory access time TACCESS) from the memory array 100 in a sequence of read events from different memory addresses. The data FRDATA read from the memory 100 in subsequent read events in such a sequence thus exhibit toggling in response to these alternate runs of data.

An exemplary circuit 100A as described herein further comprises: an edge detector 202 that is coupled to the read data port 200 and is configured to detect toggling of the data FRDATA read from the memory array 100 in subsequent read events, and triggering circuitry coupled to the edge detector 202 and configured to produce a trigger signal such as the signal Auto_FCLK to start a new read event in the sequence of subsequent read events in response (via the multiplexer 212, for instance) to the toggling of the data FRDATA indicating the end of a previous read event in the sequence of subsequent read events.

A duration of the alternate runs of data (FFF, 000, for instance) in the sequence of subsequent read events is thus indicative of the memory access time.

In an exemplary method of operation, the EWS test machine can be programmed (in a manner known per se to those of skill in the art) to store alternate runs of data (such as FFF and 000) at different memory addresses in the memory array 100.

The FSM 210 can then start a first reading in response to an (external) control signal AMStart asserted by the EWS test machine when measuring a (new) access time is desired.

Toggling of data FRDATA read from said memory (100) during the subsequent read events data can be detected with the trigger signal Auto_FCLK produced to start a new read event in the sequence of subsequent read events in response to toggling of the data FRDATA indicating the end of a previous read event in the sequence of subsequent read events.

A logic output signal AMBusy is generated by the FSM 210 which is set to a first level (“high”, for instance) when the reading flow starts and goes back to a second level (“low”, for instance) when a last reading has been performed.

A duration of the alternate runs of data in the sequence of subsequent read events is thus indicative of the memory access time.

The FSM 210 is also configured to continuously check the watchdog block 205 in order to stop the reading and assert an output warning signal AMError if any error is detected.

The external EWS machine will monitor the duration of the output signal AMBusy and count the number of cycles of the clock signal FCLK for the entire duration of the run or reading events, corresponding to AMBusy at high level.

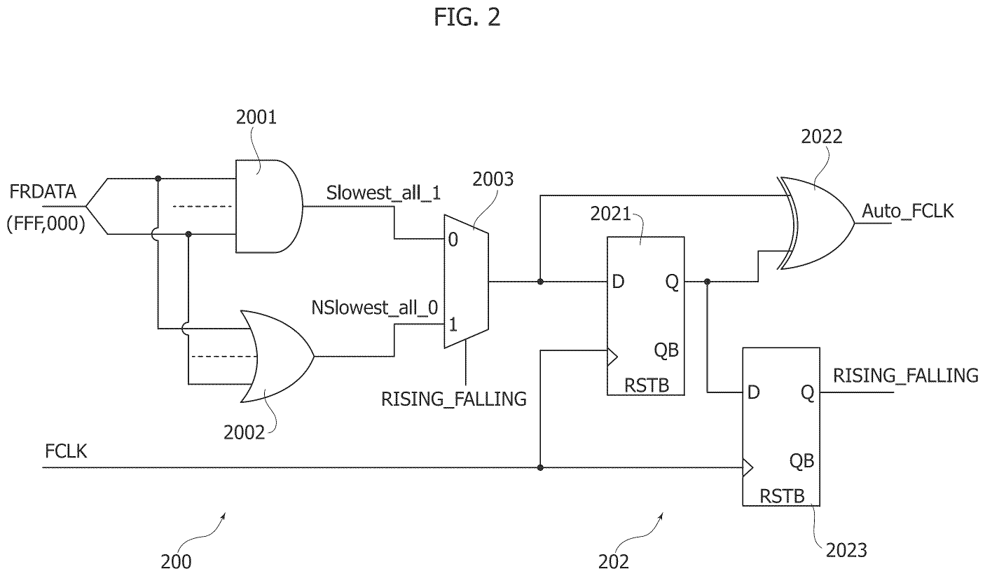

FIG. 2 is a circuit diagram of possible implementation details of circuit architecture as described herein, primarily in respect of the read data port 200 and the edge detector 202 to produce an “automatic” clock signal Auto_FCLK.

As illustrated in FIG. 2, the data FRDATA read from the memory array 100 are supplied to the inputs of: an AND gate 2001 that provides as an output a first signal Slowest_all_1 indicative of the slowest sequence of all “1's” in the data FRDATA; an OR gate 2002 that provides as an output a second signal NSlowest_all_0 indicative of the slowest sequence of all “0's” in the data FRDATA.

The signals Slowest_all_1 and NSlowest_all_0 are applied to the inputs of a multiplexer 2003 that outputs either of these signals as a function of a “state” signal RISING_FALLING obtained as discussed in the following.

The output signal from the multiplexer 2003 is applied to the D input of a synchronizing flip-flop 2021 clocked by the signal FCLK with the Q output from the flip-flop 2021 applied to one of the inputs of an EX-OR gate 2022 whose other input receives the output from the multiplexer 2003 and produces the signal Auto_FCLK as an output.

Reference 2023 denotes another flip-flop clocked by the clock signal FCLK that receives at its D input the Q output of the flip-flop 2021 and produces a its Q output the signal RISING_FALLING.

FIG. 3 is a time diagram that illustrates possible finite operation of the circuitry illustrated in FIG. 2.

Specifically, FIG. 3 illustrates, against a common abscissa time scale t, possible time behaviors of the following signals (from top to bottom):
a read signal FRDATA, showing—by way of example—a possible alternation of “all 1” four-bit runs (hexadecimal FFF) and “all 0” four-bit runs (hexadecimal 000), the cumulative duration of these latter being indicative of an access time TACCESS and represented by reference 3003;
the clock signal FCLK;
the (first) signal Slowest_all_1;
the (second) signal NSlowest_all_0;
the “internal” clock signal Auto_FCLK; and
the “state” signal RISING/FALLING.

During the commutation FFF to 000 of the FRDATA: a rising edge of Auto_FCLK is generated as a direct consequence of the falling edge of the NSlowest_all_0—this is indicated in the figure by the arrow 3001, and a falling edge of Auto_FCLK is generated when the synchronization flop 2021 samples the NSlowest_all_0 (synchronization flops require by design two clock cycles)—this is indicated in the figure by the arrow 3002.

A basic idea underlying the solutions as described herein is thus to use toggling of data FRDATA read from the memory 100, as represented by the signal RISING/FALLING to generate a new clock Auto_FCLK and to use this new clock to launch a new reading.

The readings are counted (in the counter 204, for instance) up to a predefined number and the entire duration is measured (by the EWS machine, for instance) with the possibility of using a (low frequency) external clock FCLK as a time basis for that measurement/calculation.

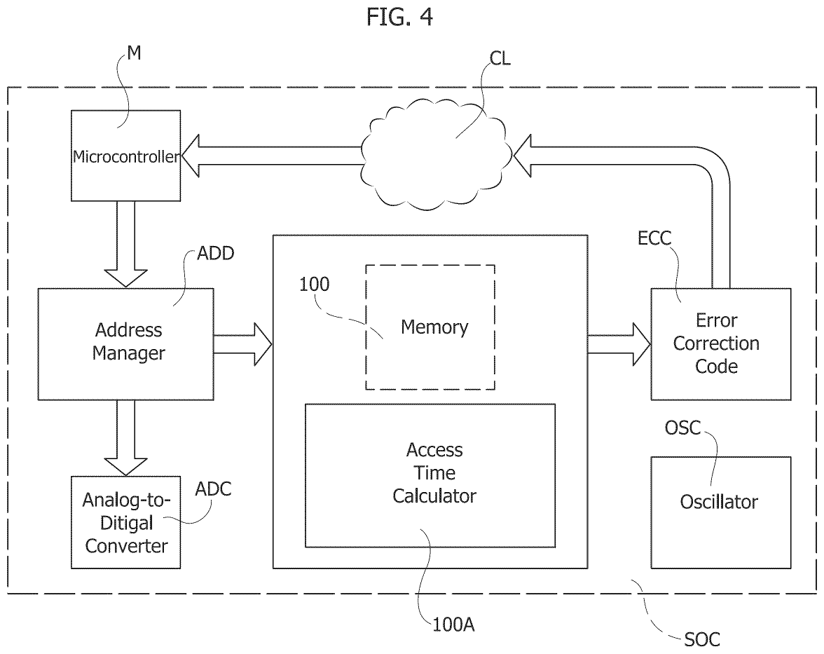

To summarize, a circuit as described herein (designated 100A in FIG. 1 and in FIG. 4) comprises a read data port 200 (including for instance the elements 2001, 2002 in the diagram of FIG. 2) configured to be coupled to a memory array 100 (which, as noted, per se may be a distinct element from the circuit 100A) having stored therein—possibly loaded via an EWS test machine—alternate runs of data (FFF, 000, for instance) at different memory addresses. The read data port 200 is configured to receive data FRDATA read from the memory array 100 with a memory access time TACCESS in a sequence of read events from different memory addresses. The data FRDATA read from the memory 100 in subsequent read events in the sequence thus exhibit toggling (see the signal RISING/FALLING, for instance) in response to the runs of date being alternate runs of data (FFF, 000, for instance).

An edge detector 202 (including for instance the elements 2021, 2023 in the diagram of FIG. 2) coupled to the read data check of read data port 200 is provided to detect toggling of the data FRDATA read from the memory array 100 in subsequent read events data.

Triggering circuitry (including for instance the elements 2021, 2022 in the diagram of FIG. 2) coupled to the edge detector 202 is configured to produce a trigger signal Auto_FCLK to start a new read event in the sequence of subsequent read events in response (via the multiplexer 212, for instance) to the toggling of the data FRDATA indicating (vie the signal Auto_FCLK) of a previous read event in the sequence of subsequent read events.

A duration of said alternate runs of data (FFF, 000) in said sequence of subsequent read events (which can be measured—in a manner known per se to those of skill in the art—by the EWS machine) is thus indicative of the memory access time (TACCESS).

As visible in FIG. 3, for instance, due to the read signal FRDATA showing a possible alternation of “all 1” four-bit runs (hexadecimal FFF) and “all 0” four-bit runs (hexadecimal 000), the cumulative duration of these latter is indicative of the access time TACCESS.

Solutions as described herein uses a finite state machine (FSM 210) to launch a sequence of n reads at different addresses (as calculated by the calculator block 206) with alternate data with each toggle (signal RISING_FALLING) of the data triggering, via the signal Auto_CLK the start of a next read.

Each read will then start independently of the external clock FCLK in so far as the reading action is driven, via the signal Auto_CLK received via the multiplexer 212, (only) by the end of previous read.

The proposed solution uses an FSM 210 to launch a sequence of n reading at different addresses with alternate data FFF, 000: alternate data is a quite used pattern as an example in checkerboard test of a memory array.

Each toggle of the data FRDATA will trigger the start of the following reading. Each reading will then start independently of the external clock FCLK in so far as it will be driven (only) by the end of previous reading.

An external clock such as FCLK is used (only) to measure the entire length of a full run. Error in the average measure will be plus or minus one cycle of the clock cycle of the signal FCLK over the entire run.

For instance (again merely by way of non-limiting example) with a signal FCLK having a period Tfclk of 2.5 ns and a full run length of n=100 the error on the average access time will be plus or minus 0.025 ns.

It is noted that in the exemplary implementation presented herein Tfclk<(Tacc/3) where Tacc is the access time in so far as at least three clock cycles of FCLK will be involved in each reading.

As described herein by way of example, the access time calculator circuit 100A may comprise an address calculator 206 triggered by the trigger signal Auto_FCLK and configured to produce different memory addresses MEMADDRESS to the memory array 100 to be used in the sequence of read events from different memory addresses.

Advantageously, the circuit 100A comprises a finite state machine, FSM 210 that is configured (for instance by being coupled to the read counter 204, to the address calculator 206 and the multiplexer 212, 214) to implement a sequence of read events from different memory addresses as discussed previously.

As illustrated, the finite state machine 210 comprises a first input configured to receive (from an EWS test machine, for instance) a start signal AMStart to start the sequence of subsequent read events from different memory addresses as well as a second input configured to receive the a (low-frequency) clock signal FLCK.

As visible in the diagram of FIG. 3, the finite state machine 210 is configured to determine—that is to calculate, possibly in cooperation with an EWS test machine—the (cumulative) duration of the alternate runs of data read in the sequence of subsequent read events started by the start signal AMStart based on the clock signal FCLK.

Advantageously, a counter 204 triggered by the trigger signal Auto_FCLK is provided in order to produce a count value of the number of subsequent read events in the sequence of subsequent read events, and the FSM 210 is configured to stop the sequence of read events from different memory addresses in response to the count value produced by counter 204 reaching a count threshold (indicated as n in the foregoing).

The solution discussed herein facilitates using one single bit of a DataBus for FRDATA or monitoring the entire Bus, by correspondingly configuring the read data port block 200, for instance:

If one bit is selected, each commutation of this bit will trigger a new reading and then the result will be the measure of the access time for a single bit.

If all the bits are monitored, a trigger will be generated when all the bit have toggled, so that the result will be the access time of the slowest bit in the DataBus.

In solutions as described herein, an external clock FCLK is used only to measure the entire length of the full run (signal AMBusy) and errors in the average measure will be plus or minus one full clock cycle of the signal FCLK over the entire run.

Solutions as described herein facilitate achieving improved accuracy in measuring the access time of a non-volatile memory (NVM), in so far as measurement is not affected by the external data path, with automatic access time calculation for the entire array, with a marked reduction of testing time.

Access time is the time involved in any read in a memory and is a parameter indicative of performance level: a high-performance memory exhibits a small access time and an accurate measurement of this parameter is highly desirable.

FIG. 4 is exemplary of possible applications of access time calculator circuitry as described herein (collectively indicated by reference 100A) associated with a memory array 100—irrespective of the related technology, wherein the resulting arrangement (memory array 100 plus access time calculator circuitry 100A) is embedded in a system-on-chip (SOC) including, by way of example, a microcontroller M, an address manager ADD, an analog-to-digital converter ADC, an error correction code (ECC) calculator, an oscillator OSC as well as any possible custom logic CL placed between the ECC and the microcontroller M.

Access time calculator circuitry 100A as described herein can provide an accurate measurement of access time at NVM level (not affected by the external paths) which is technology independent, can be applied to any memory 100.

As noted, possible applications of a circuit 100A as described herein are otherwise not limited to NVM memories embedded in a SOC. Solutions as described herein can be used whenever an accurate measurement of access time (not affected by external paths) is desired at NVM level.

Without prejudice to the underlying principles, the details and embodiments may vary, even significantly, with respect to what has been described by way of example only, without departing from the extent of protection.

The claims are an integral part of the technical teaching provided herein in respect of the embodiments.

The extent of protection is determined by the annexed claims.

1. A circuit, comprising:
a read data port configured to be coupled to a memory having stored therein alternate runs of data at different memory addresses;
wherein the read data port is configured to receive data read from said memory with a memory access time in a sequence of read events from the different memory addresses;
wherein the data read from the memory in subsequent read events in the sequence of read events exhibits toggling in response to said alternate runs of data;
an edge detector coupled to the read data port, wherein the edge detector is configured to detect toggling of data read from said memory in the subsequent read events; and
triggering circuitry coupled to the edge detector and configured to produce a trigger signal to start a new read event in said sequence of read events in response to said toggling of data which indicates an end of a previous read event in the sequence of read events;
wherein a duration of said alternate runs of data in said sequence of read events is indicative of said memory access time.

2. The circuit of claim 1, comprising an address calculator triggered by said trigger signal and configured to produce different memory addresses to said memory in said sequence of read events from different memory addresses.

3. The circuit of claim 1, comprising a finite state machine (FSM) configured to implement said sequence of read events from the different memory addresses, wherein the FSM comprises:
a first input configured to receive a start signal for controlling starting said sequence of read events from different memory addresses; and
a second input configured to receive a clock signal;
wherein the FSM is configured to determine the cumulative duration of said alternate runs of data read in the sequence of read events started by said start signal based on said clock signal.

4. The circuit of claim 3, comprising a counter triggered by said trigger signal and configured to produce a count value of the number of read events in said sequence of read events, wherein the FSM is configured to stop the sequence of read events from different memory addresses in response to the count value produced by counter reaching a count threshold.

5. The circuit of claim 1, wherein the read data port comprises:
an AND gate coupled to receive data output from the memory and provide a first signal indicative of a slowest run of logical ones in said alternate runs of data;
an OR gate coupled to receive data output from the memory and provide a second signal indicative of a slowest run of logical zeros in said alternate runs of data; and
a multiplexer configured to apply to said triggering circuitry one or the other of the first signal and the second signal based on a state signal having a first value and a second value, respectively, the state signal generated in response to toggling at the end of a previous read event in the sequence of read events.

6. The circuit of claim 5, comprising a first flip-flop and a second flip-flop clocked in synchronism with the bits of data in said alternate runs of data, wherein:
the first flip-flop had an input configured to be driven by an output of said multiplexer and receive from the multiplexer the one or the other of the first signal and the second signal;
the second flip-flop has an input configured to be driven by an output of the first flip-flop, wherein an output of the second flip-flop provides a state signal indicative of toggling of data read from said memory in the sequence of read events; and
an EX-OR gate having a first input coupled to receive from the multiplexer the one or the other of the first signal and the second signal and a second input coupled to the output of the first flip-flop, wherein an output of the EX-OR gate provides said trigger signal.

7. A memory device, comprising:
a memory including different memory addresses configured to have stored therein alternate runs of data; and
the circuit according to claim 1;
wherein the circuit is arranged with said read data port coupled to said memory;
wherein said read data port is configured to receive data read from said memory with a memory access time in the sequence of read events from the different memory addresses; and
wherein the circuit is configured to detect a duration of said alternate runs of data in said sequence of read events indicative of said memory access time.

8. The memory device of claim 7, wherein the memory comprises one of: a flash memory, a floating gate transistor memory, a magneto-resistive random-access memory or a phase change memory.

9. A method, comprising:
storing alternate runs of data at different memory addresses in a memory;
reading said alternate runs of data from said memory with a memory access time;
wherein reading comprises performing a sequence of read events from different memory addresses, with the data read from the memory in subsequent read events in the sequence of read events exhibiting a toggling in response to said alternate runs of data;
detecting toggling of data read from said memory in subsequent read events; and
producing a trigger signal to start a new read event in said sequence of read events in response to said detected toggling of data which indicates an end of a previous read event in the sequence of read events, and wherein a duration of said alternate runs of data in said sequence of read events is indicative of said memory access time.

10. The method of claim 9, wherein detecting toggling comprises:
logically ANDing data output from the memory to generate a first signal indicative of a slowest run of logical ones in said alternate runs of data; and
logically ORing data output from the memory to generate a second signal indicative of a slowest run of logical zeros in said alternate runs of data.

11. The method of claim 10, wherein producing the trigger signal comprises selecting one or the other of the first signal and the second signal based on a state signal having a first value and a second value, respectively, wherein the state signal is generated in response to toggling at the end of a previous read event in the sequence of read events.
